(19) United States
(12) Patent Application Publication
(10) Pub. No.: US 2005/0092356 A1
(43) Pub. Date: May 5, 2005

(54) Portable power supply

(75) Inventor: Takanori Sakai, Katsuragi-shi (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/972,430

(22) Filed: Oct. 26, 2004

(30) Foreign Application Priority Data
Oct. 29, 2003 (JP) 2003-369028

(51) Int. Cl. H01L 31/00

(52) U.S. Cl. 136/251; 136/291

(57) ABSTRACT

A portable power supply is foldable around a hinge. The portable power supply is provided at a side end surface of a solar cell module with a handle, and is provided at a side end surface of a solar cell module with a handle. The portable power supply is configured such that, when the portable power supply is in a folded position, an opening in the handle overlaps with an opening in the handle. According to this structure, the portable power supply can be easily carried, and can include the solar cell module having a light receiving surface, of which direction can be easily changed.

This nonprovisional application is based on Japanese Patent Application No. 2003-369028 filed with the Japan Patent Office on Oct. 29, 2003, the entire contents of which are hereby incorporated by reference.

### BACKGROUND OF THE INVENTION

1. Field of the Invention

The present invention relates to a portable power supply, which can generate electric power by receiving sunlight.

2. Description of the Background Art

Stand-alone power supply systems, which can generate electric power by receiving sunlight, have been used. As shown in FIG. 15, a conventional stand-alone power supply system includes a solar cell module 102, a rechargeable battery 103, a controller 104 controlling solar cell module 102 and rechargeable battery 103, and an AC electric load 105 connected to controller 104. These components are independent of each other, and are connected together by connection interconnections 106.

The conventional stand-alone power supply system provided with the solar cell module is made of a plurality of components, which are independent of each other, and are connected together by electric interconnections, as already described. Therefore, it is difficult to move the stand-alone power supply system for temporary use. Also, the solar cell module is usually fixed to a base or frame so that it is difficult to change a direction of a surface receiving sunlight.

### SUMMARY OF THE INVENTION

The invention has been developed for overcoming the above problem, and it is an object of the invention to provide a portable power supply allowing easy movement of a stand-alone power supply system.

Another object of the invention is to provide a portable power supply, in which attitude of a surface receiving sunlight can be easily changed.

A portable power supply of an aspect of the invention includes a first solar cell module provided with a first light receiving surface for receiving sunlight, and a second solar cell module provided with a second light receiving surface for receiving the sunlight. Also, the portable power supply includes a first handle provided to the first solar cell module, and a second handle provided to the second solar cell module. Further, the portable power supply includes a foldable portion being foldable and connecting the first and second solar cell modules together. The portable power supply is configured such that, when the foldable portion is in a folded position, an opening formed by the first handle and the first solar cell module substantially overlaps with an opening formed by the second handle and the second solar cell module.

According to the above structure, when a user grips and carries the solar cell module, the user can collectively grasp the first and second handles so that the user can easily carry the portable power supply. As a result, when the above structure are used, if only the user hooks the first and second handles on engagement members such as hooks, the above structure functions as the solar cell modules.

The first solar cell module portion is provided on a rear side of the first light receiving surface with a first attachment surface allowing attachment of a first battery pack thereto. The second solar cell module portion is provided on a rear side of the second light receiving surface with a second attachment surface allowing attachment of a second battery pack thereto. According to the above structure, attachment to and detachment from the first and second solar cell module portion of the first and second battery pack becomes easy.

According to the portable power supply of the aspect of the invention, the first battery pack is attached to the first attachment surface, and the second battery pack is attached to the second attachment surface. According to the portable power supply of the aspect of the invention, a position of the center of total gravity of the first and second solar cell modules and the first and second battery packs is determined such that the first and second light receiving surfaces form a predetermined angle with respect to the vertical direction when the first and second handles are engaged with an engagement portion. According to this structure, the performance of the solar cell can be utilized more easily and effectively.

The first handle may be arranged in a position shifted toward the light receiving surface with respect to a center in a direction of a thickness of the first solar cell module, and the second handle may be arranged in a position shifted toward the second light receiving surface with respect to a center in a direction of a thickness of the second solar cell module.

According to the above structure, when the first and second handles are engaged with the hooks or the like, respectively, each of the first and second light receiving surfaces can be easily inclined with respect to the vertical direction.

According to another aspect of the invention, a portable power supply includes a first solar cell module portion provided with a first light receiving surface for receiving sunlight, and a second solar cell module portion provided with a second light receiving surface for receiving the sunlight. Also, the portable power supply includes a foldable portion being foldable and connecting the first and second solar cell modules together. The first solar cell module has a first through hole extending in a direction of a thickness. The second solar cell module has a second through hole extending in the direction of the thickness. It is desired that the first and second through holes form a single through hole when the foldable portion is in a folded position.

According to the above structure, a string can be passed through the through holes to bind or tie the first and second solar cell modules together with the string. Thereby, such a disadvantage can be prevented that the portable power supply accidentally opens while the user is carrying the portable power supply. Therefore, the user can easily carry the portable power supply.

According to still another aspect of the invention, a portable power supply includes a first solar cell module portion provided with a first light receiving surface for receiving sunlight, and a second solar cell module portion provided with a second light receiving surface for receiving the sunlight. Also, the portable power supply includes a foldable portion being foldable and connecting the first and second solar cell modules together. A battery pack is attached to either one or each of a rear side of the first light receiving surface of the first solar cell module and a rear side of the second light receiving surface of the second solar cell module. The battery pack is provided with a handle, which is rotatable with respect to the battery pack, and can be rotated to a position fixed with respect to the battery pack.

According to the above structure, the handle can be fixed in a position inclined by a predetermined angle with respect to the light receiving surface. Thereby, the handle can be used as a stand to keep the light receiving surface substantially perpendicular to the incident direction of the sunlight.

Further, the battery pack may be provided with a scale allowing measurement of an angle between a ground surface and the first or second light receiving surface. It is desired that the battery pack is internally provided with a measuring member having a scale allowing measurement of an angle between a ground surface and the first or second light receiving surface, and the measuring member can be taken out from the battery pack for measuring the above angle. This structure allows easy determination of the angle between the light receiving surface and the direction of the sunlight.

It is desired that the battery pack has at least one of a battery charger, an input terminal of a DC (Direct Current) power supply, an input terminal of an AC (Alternative Current) power supply, a DC output terminal for a load and an AC output terminal, for a load.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows light receiving sides of solar cell modules, which can be viewed when a portable power supply of an embodiment is open.

FIG. 2 is a side view of the portable power supply in a closed position according to the embodiment.

FIG. 3 shows a side surface of a battery pack, which can be viewed when the portable power supply of the embodiment is closed.

FIG. 4 shows a state of the portable power supply of the embodiment attained immediately after handles are engaged with hooks.

FIG. 5 shows a state of the portable power supply of the embodiment attained when a predetermined time elapses after the handles are engaged with the hooks.

FIG. 6 shows through holes formed in four corners of each solar cell module of the portable power supply of the embodiment, respectively.

FIG. 7 shows a closed state of the portable power supply shown in FIG. 6.

FIG. 8 shows a state, in which the solar cell modules shown in FIG. 7 are tied together with strings passing through the through holes in the portable power supply to prevent opening of the portable power supply.

FIG. 9 shows a portable power supply of an embodiment provided with handles rotatable with respect to battery packs.

FIG. 10 is a front view of the battery pack with the handle shown in FIG. 9.

FIG. 11 is a side view of the portable power supply with the battery packs having the handles in FIG. 9.

FIG. 12 shows a state of the portable power supply of the embodiment, in which the rotated handles of the battery packs are used as a stand.

FIG. 13 shows a scale formed on a side end surface of the battery pack of the portable power supply of the embodiment.

FIG. 14 shows a state of the portable power supply of the embodiment, in which an angle gauge inserted into the battery pack is taken out.

FIG. 15 shows a conventional stand-alone power supply system.

### DESCRIPTION OF THE PREFERRED EMBODIMENTS

A portable power supply of an embodiment of the invention will now be described with reference to the drawings.

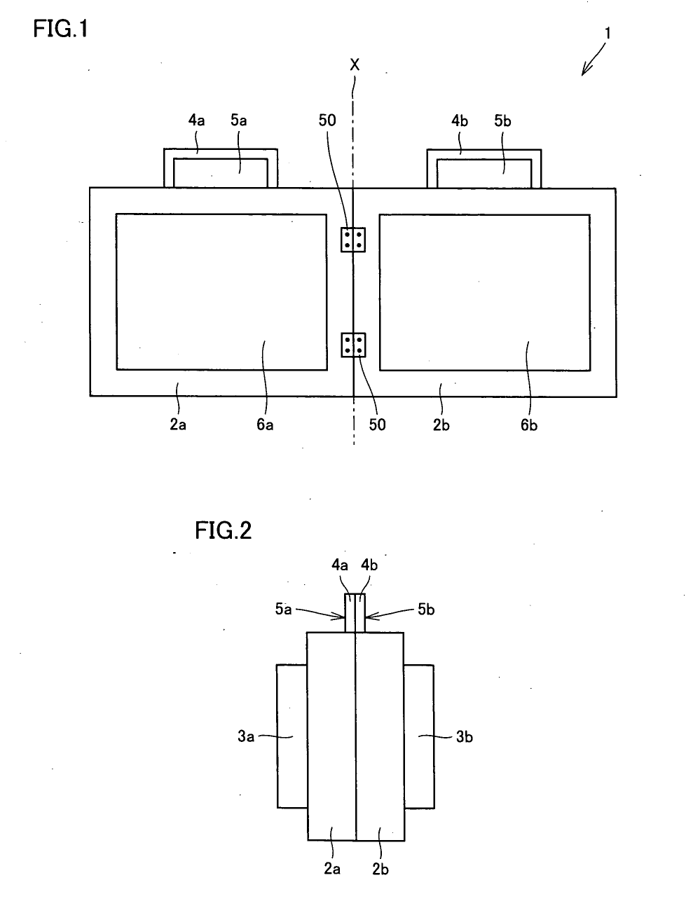

As shown in FIG. 1, a portable power supply 1 of the embodiment includes solar cell modules 2a and 2b. Portable power supply 1 also includes a hinge 50, which allows folding of portable power supply 1 to oppose solar cell modules 2a and 2b to each other.

FIG. 1 shows solar cell modules 2a and 2b in an open state. As shown in FIG. 2, when portable power supply 1 is folded around a rotation axis defined by hinge 50, light receiving surface 6a of solar cell module 2a is opposed to light receiving surface 6b of solar cell module 2b.

Light receiving surface 6a is formed in one of main surfaces of solar cell module 2a, and light receiving surface 6b is formed in one of main surfaces of solar cell module 2b. According to this embodiment, each of solar cell modules 2a and 2b has a substantially flat plate-like form, and has the rectangular main surfaces.

A handle 4a is arranged on one of side end surfaces of solar cell module 2a. A handle 4b is arranged on one of side end surfaces of solar cell module 2b. Each of handles 4a and 4b may be arranged on any one of four side end surfaces of corresponding solar cell module 2a or 2b provided that it does not impede opening and closing of solar cell modules 2a and 2b. Each of handles 4a and 4b may be arranged on a rear surface opposite to corresponding light receiving surface 6a or 6b.

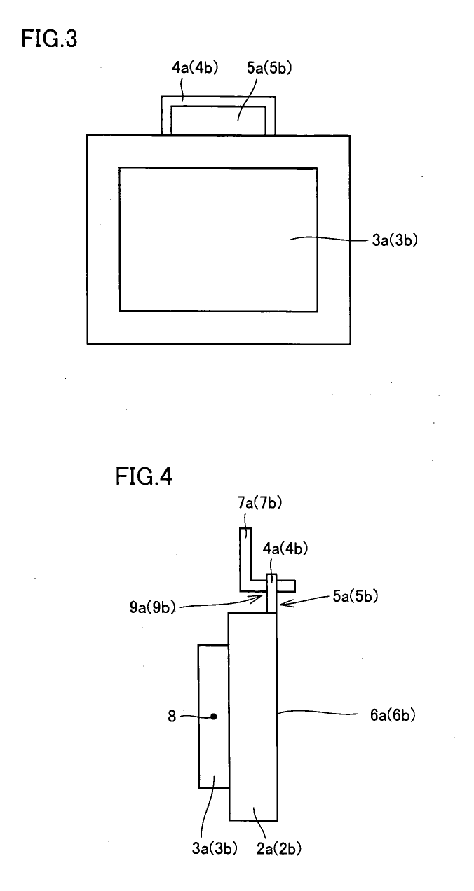

When portable power supply 1 is folded around the rotation center defined by hinge 50 to oppose solar cell modules 2a and 2b to each other, handles 4a and 4b are in contact with each other, as shown in FIG. 2. Thereby, as shown in FIG. 3, portable power supply 1 of the embodiment is closed such that openings 5a and 5b of handles 4a and 4b substantially overlap with each other. Therefore, the user can grasp handles 4a and 4b as a single handle. It is not necessary to keep handles 4a and 4b in complete contact with each other, and these may be slightly spaced if the user can substantially grasp handles 4a and 4b as a signal handle.

A battery pack 3a is engaged with a rear surface of solar cell module 2a opposite to light receiving surface 6a via an engagement member (not shown). Also, a battery pack 3b is engaged with a rear surface of solar cell module 2b opposite to light receiving surface 6b via an engagement member (not shown). Each of battery packs 3a and 3b is integrally provided with a rechargeable and a battery charger as well as a controller having functions of an input/output terminal of a DC power supply and an input/output terminal of an AC power supply.

Each of solar cell modules 2a and 2b has a maximum output of 27.5 W, and the rechargeable battery has a capacity of 12V/5 Ah. The controller has the input/output terminal of DC 12 V, and the input/output terminal of AC 100 V.

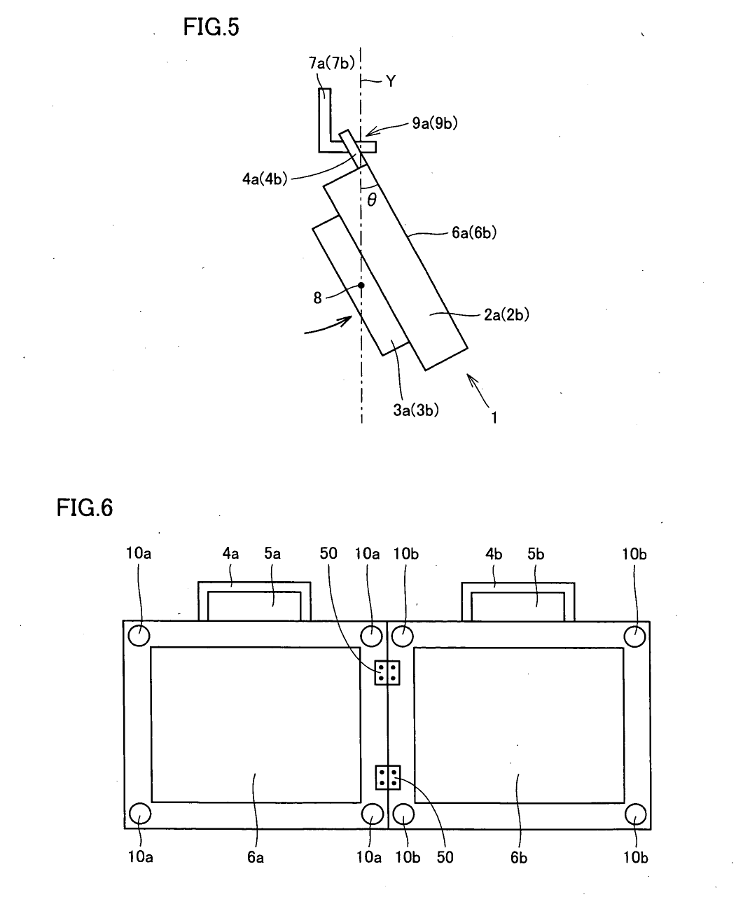

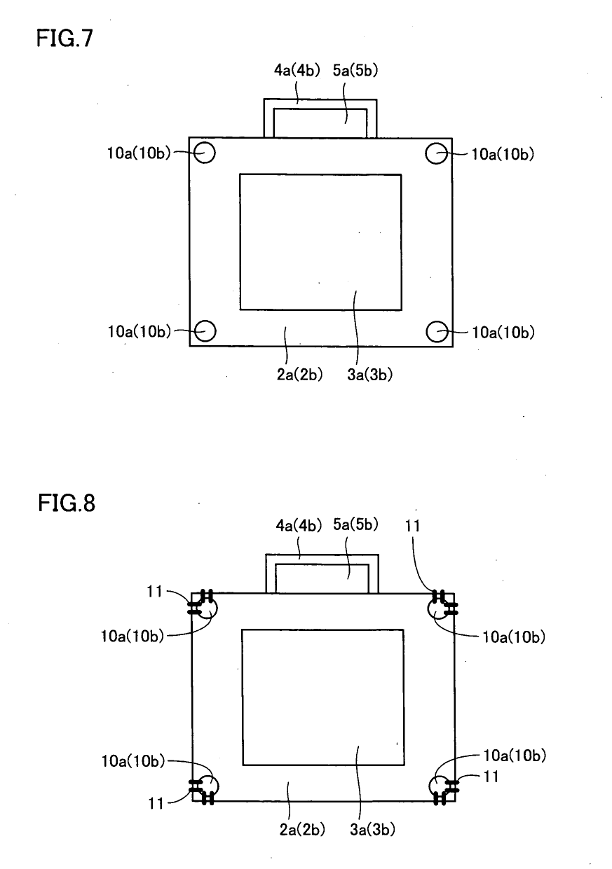

As shown in FIG. 4, when portable power supply 1 of the embodiment is used, handles 4a and 4b are engaged with hooks 7. Handle 4a is arranged in a position shifted toward light receiving surface 6a with respect to the center, which is defined in the direction of the thickness, of solar cell module 2a, and handle 4b is arranged in a position shifted toward light receiving surface 6b with respect to the center, which is defined in the direction of the thickness, of solar cell module 2b. Further, a position 8 of gravity of portable power supply 1 including battery packs 3a and 3b, which are attached to solar cell modules 2a and 2b, respectively, is lower than handles 4a and 4b. As shown in FIGS. 4 and 5, position 8 of gravity is located within battery packs 3a and 3b in this embodiment. However, it is merely required that position 8 of gravity is located in a position near the rear side of light receiving surface 6 (6b) i.e., the rear surface of solar module 2a (2b) in comparison with the position, where handle 4a (4b) is attached to battery pack 3a (3b).

According to portable power supply 1 described above, light receiving surfaces. 6a and 6b are inclined to form an angle θ with respect to vertical direction Y around rotation centers defined by respective points of contact between handles 4a and 4b and hooks 7a and 7b. Therefore, by hooking handles 4a and 4b on hooks 7a and 7b, respectively, light receiving surfaces 6a and 6b can be positioned perpendicular to the incident direction of the sunlight to the extent possible without using any other structure. Therefore, the solar cell modules can be arranged by a simple manner to allow effective charging.

As shown in FIG. 6, solar cell module 2a is provided at its four corners with through holes 10a, respectively. Solar cell module 2b is provided at its four corners with through holes 10b, respectively. Through holes 10a and 10b are positioned such that each through hole 10a and corresponding one through hole 10b form a single through hole when portable power supply 1 is folded around the rotation axis defined by hinge 50 to oppose light receiving surfaces 6a and 6b to each other.

As shown in FIG. 8, therefore, a string 11 can be passed through each through hole formed of through holes 10a and 10b in each corner, and solar cell modules 2a and 2b can be tied together with strings 11. Thereby, it is possible to prevent such an unpreferred situation that portable power supply 1 opens to form an angular space between solar cell modules 2a and 2b while it is being carried.

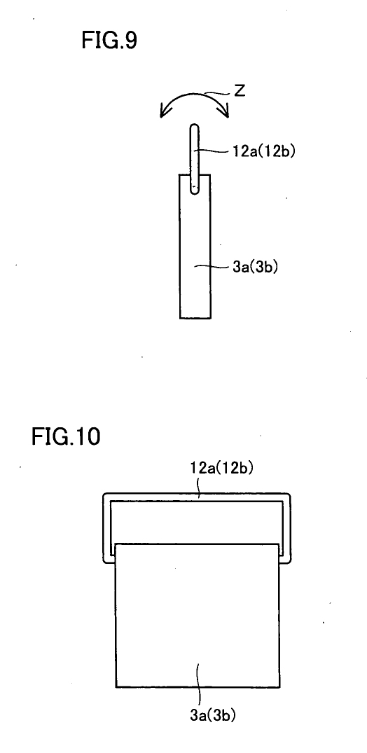

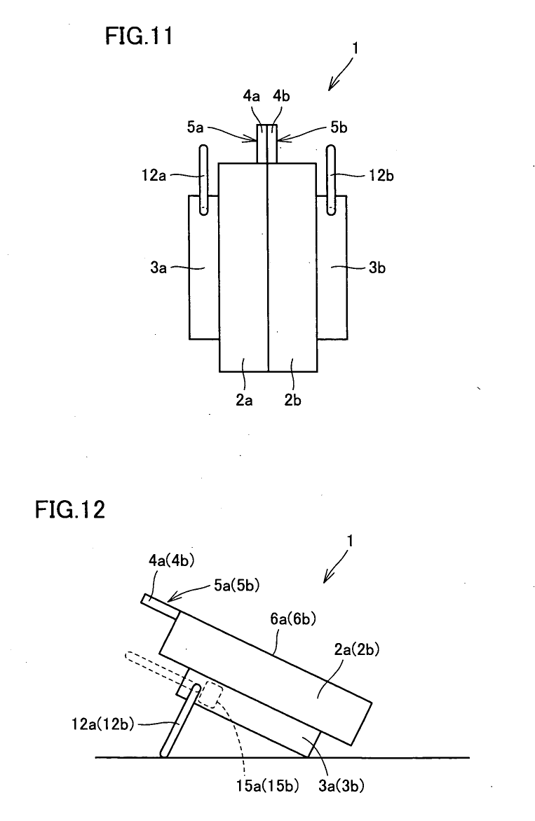

In the foregoing embodiment, battery pack 3 is not provided with any handle for carrying it. However, as shown in FIGS. 9 and 10, handles 12a and 12b may be arranged on battery packs 3a and 3b, respectively. Handles 12a and 12b may be rotatable, as indicated by an arrow Z in FIG. 9, with respect to solar cell modules 2a and 2b, respectively. FIG. 11 shows a structure, in which battery packs 3a and 3b provided with handles 12a and 12b are attached to solar cell modules 2a and 2b, respectively.

As shown in FIG. 12, when handles 12a and 12b rotate the same predetermined angle with respect to battery packs 3a and 3b, handles 12a and 12b are engaged with engagement portions 15a and 15b arranged within battery packs 3a and 3b, respectively. Engagement portions 15a and 15b can fix handles 12a and 12b in a stepwise-varying angular position. Therefore, the direction, in which handles 12a and 12b extend, can be changed stepwise with respect to the direction perpendicular to light receiving surfaces 6a and 6b of battery packs 3a and 3b, and the positional relationship between handles 12a and 12b and battery packs 3a and 3b can be fixed after changing the above direction. If engagement portions 15a and 15b are not employed, handles 12a and 12b and battery packs 3a and 3b may be configured to fix the positional relationship between them by frictional forces between handles 12a and 12b and battery packs 3a and 3b.

According to the above structure, handles 12a and 12b can be used as a stand supporting solar cell modules 2a and 2b. Thereby, the direction or the attitude of light receiving surfaces 6a and 6b with respect to the incident direction of the sunlight can be easily changed. Since handles 12a and 12b are directly used as the stand, it is not necessary to provide a dedicated stand. Therefore, battery packs 3a and 3b can have simple structures.

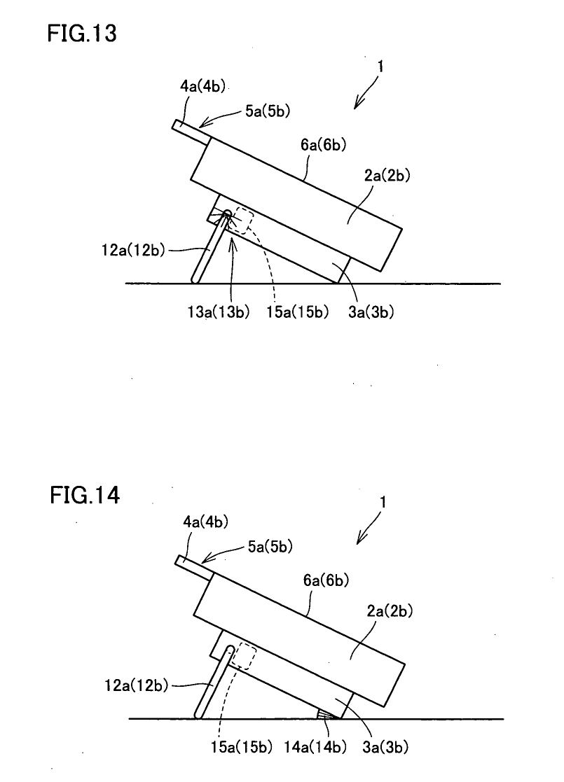

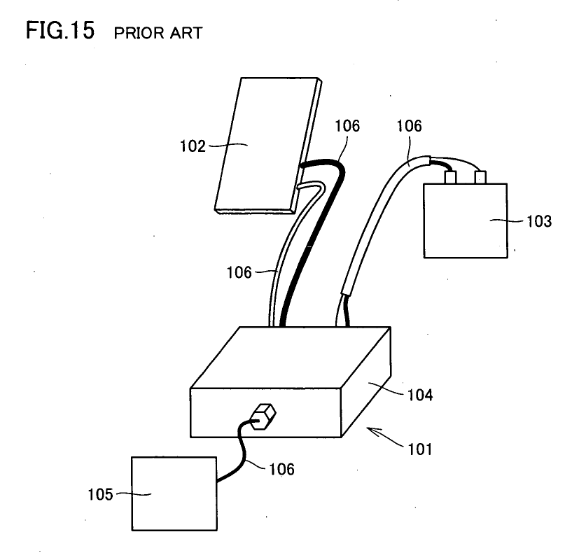

Further, battery packs 3a and 3b may be provided at the side end surfaces, as shown in FIG. 13, with scales 13a and 13b for measuring the angle between the direction of extension of handles 12a and 12b and a reference direction of battery packs 3a and 3b, i.e., a rotation angle of handles 12a and 12b with respect to battery packs 3a and 3b, respectively. By measuring the angle between the extension direction of handles 12a and 12b and the reference direction of battery packs 3a and 3b, the angle of light receiving surfaces 6a and 6b with respect to the ground surface can be easily determined.

In stead of scales 13a and 13b, as shown in FIG. 14, angle gauges 14a and 14b with scales may be inserted into battery packs 3a and 3b. For measuring the angle of light receiving surfaces 6a and 6b with respect to the ground surface, angle gauges 14a and 14b are taken out from battery packs 3a and 3b, and are located in contact with the ground surface. According to this manner, the angle of light receiving surfaces 6a and 6b with respect to the ground surface can be easily determined.

Consequently, the user, who determined the angle of the sun from the date and time, can change the position or the attitude of portable power supply 1 so that light receiving surfaces 6a and 6b can perpendicularly receive the incident sunlight as much as possible.

Although the present invention has been described and illustrated in detail, it is clearly understood that the same is by way of illustration and example only and is not to be taken by way of limitation, the spirit and scope of the present invention being limited only by the terms of the appended claims.

1. A portable power supply comprising:
a first solar cell module provided with a first light receiving surface for receiving sunlight;
a second solar cell module provided with a second light receiving surface for receiving the sunlight;
a first handle provided on said first solar cell module;
a second handle provided on said second solar cell module; and
a foldable portion being foldable and connecting said first and second solar cell modules together, wherein
said portable power supply is configured such that, when said foldable portion is in a folded position, an opening formed by said first handle and said first solar cell module substantially overlaps with an opening formed by said second handle and said second solar cell module.

2. The portable power supply according to claim 1, wherein
said first solar cell module is provided on a rear side of said first light receiving surface with a first attachment surface allowing attachment of a first battery pack thereto, and
said second solar cell module is provided on a rear side of said second light receiving surface with a second attachment surface allowing attachment of a second battery pack thereto.

3. The portable power supply according to claim 2, wherein
said first battery pack is attached to said first attachment surface, and said second battery pack is attached to said second attachment surface, and
a position of the center of total gravity of said first and second solar cell modules and said first and second battery packs is determined such that said first and second light receiving surfaces form a predetermined angle with respect to the vertical direction when said first and second handles are engaged with an engagement portion.

4. The portable power supply according to claim 1, wherein
said first handle is arranged in a position shifted toward said light receiving surface with respect to a center in a direction of a thickness of said first solar cell module, and said second handle is arranged in a position shifted toward said second light receiving surface with respect to a center in a direction of a thickness of said second solar cell module.

5. A portable power supply comprising:
a first solar cell module provided with a first light receiving surface for receiving sunlight;
a second solar cell module provided with a second light receiving surface for receiving the sunlight; and
a foldable portion being foldable and connecting said first and second solar cell modules together, wherein
said first solar cell module has a first through hole extending in a direction of a thickness,
said second solar cell module has a second through hole extending in the direction of the thickness, and
said first and second through holes form a single through hole when said foldable portion is in a folded position.

6. A portable power supply comprising:
a first solar cell module provided with a first light receiving surface for receiving sunlight;
a second solar cell module provided with a second light receiving surface for receiving the sunlight; and
a foldable portion being foldable and connecting said first and second solar cell modules together, wherein
a battery pack is attached to either one or each of a rear side of said first light receiving surface of said first solar cell module and a rear side of said second light receiving surface of said second solar cell module, and
said battery pack is provided with a handle being rotatable with respect to said battery pack and being rotated to a position fixed with respect to said battery pack.

7. The portable power supply according to claim 6, wherein
said battery pack is provided with a scale allowing measurement of an angle between a ground surface and said first or second light receiving surface.

8. The portable power supply according to claim 6, wherein
said battery pack is internally provided with a measuring member having a scale allowing measurement of an angle between a ground surface and said first or second light receiving surface, and
said measuring member can be taken out from said battery pack for measuring said angle.

9. The portable power supply according to claim 6, wherein
said battery pack has at least one of a battery charger, an input terminal of a DC power supply, an input terminal of an AC power supply, a DC output terminal for a load and an AC output terminal for a load.
